(19) United States
(12) Patent Application Publication
(10) Pub. No.: US 2011/0284063 A1
(43) Pub. Date: Nov. 24, 2011

(54) HIGH EFFICIENCY DYE-SENSITIZED SOLAR CELL WITH LAYERED STRUCTURES

(76) Inventors: Miao Yu, Broomfield, CO (US); Wei Zhang, Superior, CO (US); John L. Falconer, Boulder, CO (US); Richard D. Noble, Boulder, CO (US)

(21) Appl. No.: 13/114,948

(22) Filed: May 24, 2011

Related U.S. Application Data
(60) Provisional application No. 61/347,738, filed on May 24, 2010.

(51) Int. Cl. H01L 31/0224; H01L 31/06; B82Y 99/00; B82Y 40/00

(52) U.S. Cl. 136/255; 438/85; 257/E31.124; 977/773; 977/948

(57) ABSTRACT

A dye-sensitized solar cell (DSSC) is provided. The DSSC anode includes a first electron-collecting layer deposited on a substrate and a first electron-transporting layer deposited on the first electron-collecting layer, the first electron-transporting layer containing light-absorbing dye. The DSSC anode also includes a second nanoporous electron-collecting layer deposited on the first electron-transporting layer; and a second electron-transporting layer deposited on the second porous electron-collecting layer, the second electron-transporting layer containing light-absorbing dye. Methods of fabricating the DSSC anode are also provided.

### CROSS-REFERENCE TO RELATED APPLICATIONS

This non-provisional application claims the benefit of the filing date of U.S. Provisional Patent Application No. 61/347,738, filed May 24, 2010, entitled “HIGH EFFICIENCY DYE-SENSITIZED SOLAR CELL WITH LAYERED STRUCTURES,” the entire content of which is incorporated herein by reference.

### BACKGROUND

1. Field of the Invention

The present disclosure relates to a dye-sensitized solar cell (DSSC) with a layered structure and processes for making and using the same.

2. Description of the Related Art

A solar cell is a device that converts energy of sunlight into electricity. Traditional solar cells are fabricated from semiconductor materials, such as silicon. Silicon-based solar cells generally implement semiconductor layers to produce electric current by exploiting the photovoltaic effects that exist at semiconductor junctions. Another type of solar cell, also known as dye-sensitized solar cell (DSSC), utilizes dyes to absorb incoming light in order to produce excited electrons. A dye-sensitized solar cell typically contains two planar conducting electrodes arranged in a sandwiched configuration. A dye-coated material forms the middle layer(s) that separate the two electrodes. These middle layer(s) may be constructed of mesoporous materials, such as titanium dioxide (TiO₂), which provide high surface area to enhance light absorption by the dyes. The remaining space between the electrodes may be filled with an electrolyte, which typically contains an oxidation/reduction pair, such as triiodide/iodide.

The advantages of DSSCs include, for example, device stability, low-cost device fabrication, efficient solar-to electrical energy conversion (“energy conversion”), and so on. The theoretical maximum energy conversion efficiency of DSSCs has been calculated to be approximately 33%. Due to various technical reasons, however, the currently achievable energy conversion in a DSSC still lags behind that of commercial silicon solar cells. For example, the most efficient DSSC has energy conversion efficiency at ˜11%, which is less than half that of crystalline silicon-based solar cells at 24.4%.

A challenging aspect of DSSCs involves improving light harvesting in the long wavelength range (650 nm-900 nm). To date, DSSCs with the highest efficiencies are obtained by using a light-absorbing dye, such as that termed N749 or “Black Dye” (Dyesol, Australia). DSSCs fabricated with N749 generate photocurrent densities of approximately 21 mA/cm². The theoretical maximum current for N749, with an absorption onset of 900 nm, is 33 mA/cm². However, N749 has a low molar extinction coefficient and low Incident-Photon-to-Electron Conversion Efficiency (IPCE) within the long wavelength range.

One approach aimed at improving IPCE within the long wavelength range involves increasing the thickness of the mesoporous TiO₂ layer. A thicker TiO₂ layer has greater surface area for more light-absorbing dye molecules to attach to, which translates into more excited electrons upon exposure to sunlight. However, a thicker TiO₂ layer may result in extensive electron loss. Electron loss occurs because electrons migrate in a nanoparticle network through a trap-limited diffusion process. In other words, photo-generated electrons interact with traps during diffusion by a “random walk” mechanism through the TiO₂ materials. An injected electron may experience a million trapping events before either reaching the collecting electrode or recombining with a hole. For example, an electron may encounter a trapping event when interacting with an oxidizing species, such as I₃⁻ in the electrolyte on the TiO₂ surface. Electron diffusion distance is typically 10-15 μm in mesoporous TiO₂, which, in turn, limits the thicknesses of the mesoporous TiO₂ layer to 10-15 μm in order to minimize electron loss.

### SUMMARY

The presently disclosed instrumentalities advance the art by providing improved solar cells having increased energy conversion efficiencies.

In an embodiment, a dye-sensitized solar cell (DSSC) anode is provided. The DSSC anode includes a glass substrate; a first electron-collecting layer deposited on the substrate, the first electron-collecting layer permitting diffusion of electrolytes; and a first electron-transporting layer deposited on the first electron-collecting layer, the first electron-transporting layer containing light-absorbing dye. The DSSC anode also includes a second nanoporous electron-collecting layer deposited on the first electron-transporting layer, the second electron-collecting layer permitting diffusion of electrolytes; and a second electron-transporting layer deposited on the second nanoporous electron-collecting layer, the second electron-transporting layer containing light-absorbing dye. Each of the first and second electron-transporting layers includes a material selected from the group consisting of titanium dioxide (TiO₂), niobium pentoxide (Nb₂O₅), and zinc oxide (ZnO). A total thickness of the first and second electron-transporting layers is greater than or equal to the electron diffusion limit of the electron-transporting layer material. The first electron-collecting layer and second layers are thin (about 1 μm).

In a particular embodiment, each of the first and second electron-collecting layers includes indium tin oxide (ITO) nanoparticles. The ITO particles are passivated with a layer of TiO₂. The thickness of the first and second electron-collecting layer is about 1 μm. The nanoporous ITO layer includes nanoparticles with sizes ranging from 15 nm to 60 nm. The ITO includes 10 mol % Sn⁴⁺ and 90 mol % In³⁺.

In an embodiment, a method for fabricating a DSSC anode is provided. The method includes depositing a first electron-collecting layer over a substrate and forming a first electron-transporting layer over the first electron-collecting layer. The method also includes depositing a second nanoporous electron-collecting layer over the first electron-transporting layer and forming a second electron-transporting layer over the second nanoporous electron-collecting layer. Each of the first and second electron-transporting layers includes a material selected from the group consisting of titanium dioxide (TiO₂), niobium pentoxide (Nb₂O₅), and zinc oxide (ZnO). The second nanoporous electron-collecting layers includes indium tin oxide (ITO) nanoparticles. The method also includes passivating a TiO₂ layer over the second nanoporous electron-collecting layer by atomic layer deposition. The first electron-collecting layer includes at least one of indium tin oxide (ITO) nanoparticles and fluorinated tin oxide (FTO). The total thickness of the first and second electron-transporting layer is equal to or greater than greater than or equal to the electron diffusion limit of the electron-transporting layer material. The first and second electron-transporting layers are mesoporous layers with pore diameters ranging from approximately 10 nm. Each of the first and second electron-collecting layer is approximately 1-2 μm thick, and has pore diameters ranging from 10 nm to 30 nm.

In an embodiment, a method for fabricating a DSSC anode is provided. The method includes depositing a dense indium tin oxide (ITO) layer over a substrate; forming a nanoporous ITO layer comprising ITO nanoparticles over the dense ITO layer. The nanoporous ITO layer has an order of magnitude higher resistivity than the dense ITO layer. The method also includes passivating a titanium dioxide (TiO₂) layer over the nanoporous ITO layer. The dense ITO layer is about 120-160 nm thick. The nanoporous ITO layer has a thickness greater than 20 μm. The TiO₂ layer is approximately 2 nm to 5 nm thick.

In one embodiment, a solar cell may contain two electrodes: a first electrode and a second electrode, and the two electrodes are preferably positioned at a distance of greater than 10 μm, more preferably, at a distance greater than 20 μm. In another embodiment, two porous layers, namely, a first porous layer and a second porous layer, may be placed between the two electrodes, and both the first porous layer and the second porous layer contain a dye-sensitized material. A dye-sensitized material is a porous material that has attached to it one or more dye molecules. The dye-sensitized material may be made of at least one metal oxide particle. Preferably, the first porous layer and the second porous layer are made of the same metal oxide particles. Examples of metal oxide include but are not limited to titanium dioxide (TiO₂), niobium pentoxide (Nb₂O₅), zinc oxide (ZnO) or combination thereof. The thickness of the first and second layers is about 1-20 μm each, or more preferably, about 10-15 μm each.

In another embodiment, a third porous layer may be placed between the first porous layer and the second porous layer. Preferably, the third porous layer is capable of collecting the electrons from the first porous layer and/or the second porous layer. The thickness of the third layer is about 0.2-5 μm, or more preferably, about 1 μm. The third porous layer is preferably made of particles that are different from those of the first and second porous layers. Example of nanoparticles that make up the third porous layer include but are not limited to indium tin oxide (ITO), fluorinated tin oxide (FTO) or combination thereof. The solar cell may contain more than one of such ITO+TiO₂ bi-layers by repeating the configuration described above.

In another embodiment, a multi-layered DSSC may contain alternating layers of electron-collecting material and electron-transporting material. In one embodiment, a multi-layered DSSC may contain an electron-transporting material that is made of TiO₂ nanoparticles. In another embodiment, a DSSC may contain electron-collecting material that is made of ITO nanoparticles.

In another embodiment, passivation of the surface of ITO nanoparticles in the ITO layer may be implemented by depositing a thin TiO₂ coating on the surface of the ITO nanoparticles. The TiO₂ coating may range from about 2 to 5 nm thick and may be deposited by using atomic layer deposition (ALD). The thin TiO₂ coating may significantly reduce the electron recombination rate, thus increasing the open-circuit voltage.

In another embodiment, the passivated TiO₂-coated nanoporous ITO layer may also serve as semiconducting support for dye molecules because this layer could provides similar surface area as TiO₂ for supporting dye molecules when their thickness are similar to that of the traditional TiO₂ dye-supporting layers. Such TiO₂-coated nanoporous ITO layer may contribute significantly to the total current because of the short electron transporting distance (2˜5 nm) before reaching the electron-collecting substrate (interconnected network of ITO nanoparticles), which significantly suppresses the recombination rate in TiO₂.

A dye-sensitized solar cell (DSSC) is provided. The DSSC includes anode structures described herein. In an embodiment, a DSSC is provided that includes an anode containing a first electron-collecting layer deposited on a substrate; a first electron-transporting layer deposited on the first electron-collecting layer, the first electron-transporting layer containing light-absorbing dye. The anode also contains a second nanoporous electron-collecting layer deposited on the first electron-transporting layer; and a second electron-transporting layer deposited on the second porous electron-collecting layer, the second electron-transporting layer containing light-absorbing dye. The DSSC also includes a cathode in electrical connection with the anode. In other embodiments, the anode has more than two electron transporting layers and more than two electron-collecting layers.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings.

### BRIEF DESCRIPTION OF THE FIGURES

FIG. 1 illustrates electricity generation in a dye-sensitized solar cell (DSSC) of the prior art.

FIG. 2A-2F show exemplary DSSC anode structures, in embodiments.

FIG. 3 shows a SEM image of an exemplary 1 μm thick ITO film including 5 mol % Sn⁺⁴ and 95% mol % In⁺³.

FIG. 4 shows a SEM image of an exemplary 1 μm thick ITO film including 10 mol % Sn⁺⁴ and 90% mol % In⁺³.

FIG. 5 is a graph showing exemplary UV-Vis transmission spectra of 1 μm thick ITO films.

FIG. 6 is a graph showing surface resistance of exemplary 1 μm thick ITO films.

FIG. 7 is a digital picture showing exemplary light transparency of ITO coated glass plates.

FIG. 8 is a schematic diagram and a SEM image showing a cross-section of an exemplary multi-layered DSSC structure.

FIG. 9 shows SEM images illustrating the structure of an exemplary multi-layered DSSC.

FIG. 10 shows characterization of an exemplary multi-layered DSSC structure by SEM and energy-dispersive X-ray spectroscopy (EDS).

FIG. 11 is a graph showing photocurrent-voltage (I-V) curves of exemplary DSSC anode structures with input energy of 50 mW/cm².

FIG. 12 is a graph showing open circuit voltage decay of exemplary DSSC anode structures.

FIG. 13 is a graph showing I-V curves for exemplary DSSCs having different cell sizes.

FIG. 14 is a graph showing I-V curves for exemplary DSSCs.

FIG. 15 is a graph showing I-V curves for various exemplary DSSC structures.

FIG. 16 is a graph showing open circuit potential decays for various exemplary DSSCs.

FIG. 17 shows an exemplary two-layer DSSC anode in an embodiment.

### DETAILED DESCRIPTION

The present disclosure may be understood by reference to the following detailed description taken in conjunction with the drawings as described below. For purposes of illustrative clarity, certain elements in the drawings are not drawn to scale.

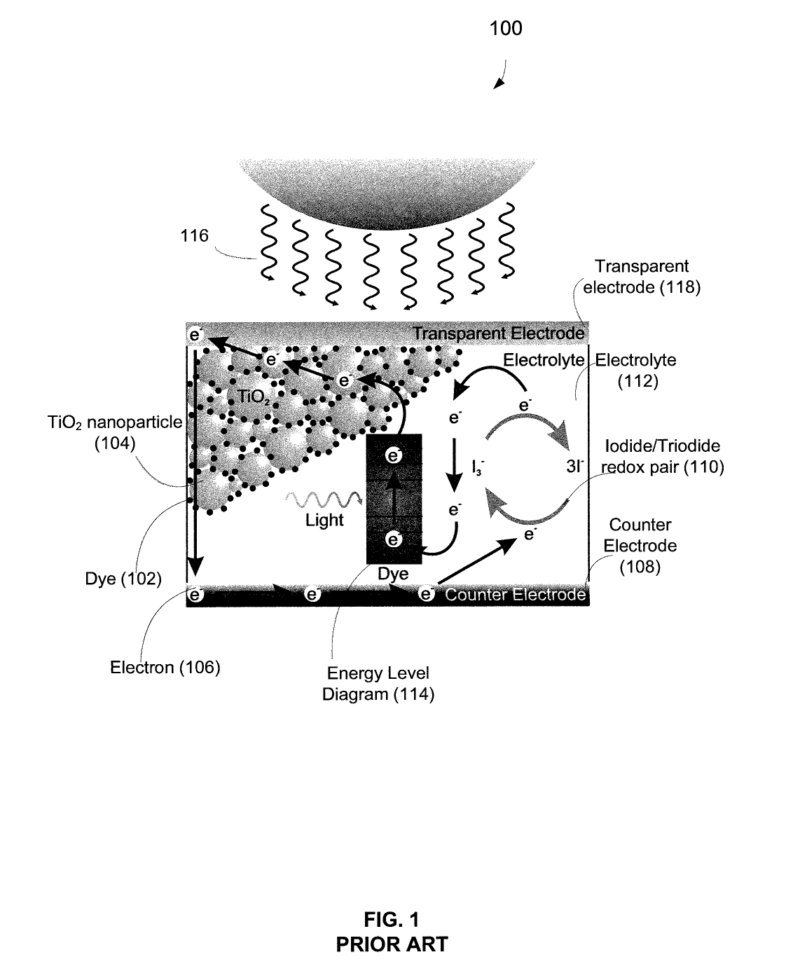

FIG. 1 illustrates a mechanism for generating electricity for a conventional DSSC 100. Solar energy 116 passes through a transparent electrode 118 and encounters dye 102, which is present on the surface of a titanium dioxide (TiO₂) nanoparticle 104. Solar energy absorption promotes electron 106, within dye 102, to an excited state, where electron 106 is further injected into TiO₂ nanoparticle 104. Electron 106 diffuses into transparent electrode 100 and is further transported via external circuit to counter electrode 108. Dye 102 is regenerated via electron abstraction from iodide, which is present in an iodide/triiodide redox pair 110 in electrolyte 112 between electrodes 118 and 108. An energy level diagram 114 is also presented.

The present disclosure provides improved DSSCs with multi-layered structures that improve the efficiency of solar-to electrical energy conversion by enhancing light absorption in the long wavelength range and minimizing electron-hole recombination pathways. Multi-layered DSSCs contain structures with alternating layers of electron-collecting material and electron-transporting material. Examples of electron-collecting materials include indium tin oxide (ITO) and fluorinated tin oxide (FTO). Electron-collecting materials also permit diffusion of electrolytes. In one embodiment, nanoporous ITO material permits electron collection and transport of the redox pair, (I⁻/I₃⁻). Examples of electron-transporting materials include titanium dioxide (TiO₂), niobium pentoxide (Nb₂O₅), and zinc oxide (ZnO).

In one embodiment, a multi-layered DSSC includes electron-collecting, nanoporous ITO layers embedded between mesoporous electron-transporting TiO₂ layers. The term “nanoporous” refers to materials having porous structures with pore diameters preferably between 0.1 nm and 1000 nm. The term “mesoporous” refers to a type of nanoporous material with pore diameters ranging between approximately 2 nm and 50 nm. In one embodiment, the electron-transporting TiO₂ layer of a DSSC includes TiO₂ nanoparticles having light-absorbing dyes adherent to their surfaces. In one embodiment, a DSSC may contain electron-collecting electrodes including dense ITO films made from ITO nanoparticles and/or nanoporous ITO films made from ITO nanoparticles. Multi-layered DSSCs permit efficient collection of photo-generated electrons because electrons require short-distance diffusion through the electron-transporting material to encounter electron-collecting material. Electron diffusion distance depends on, for example, porosity and chemical composition of the electron transporting material as well as the methods of forming the electron transporting material as part of an electrode. In one embodiment, photo-generated electrons in a DSSC (see FIG. 1), except for electrons generated at the top TiO₂ layer, maximally require diffusion through half of a TiO₂ layer to reach the electron-collecting ITO layer, therefore permitting efficient collection of photo-generated electrons.

In one embodiment, a DSSC structure includes nanoporous electron-collecting layers, such as ITO layers, embedded between electron-transporting layers, such as mesoporous TiO₂ layers, to enable electron collection from electron-transporting layers having a total thickness that is approximately equal to or greater than the electron diffusion distance limitation for the electron-transporting layer. In an embodiment in which the electron-transporting layers are mesoporous TiO₂ layers, the combined thickness of mesoporous TiO₂ layers is approximately 15 μm or greater. In one embodiment, a multi-layered DSSC permits efficient collection of electrons in TiO₂ layers having thickness greater than 15 μm, thus improving visible light harvesting in the long wavelength range. It is to be understood that when materials other than TiO₂ are used as the electron-transporting materials, the thickness of the electron-transporting materials may be adjusted based upon the identity, structure, and/or chemical composition of these materials.

As used herein, “ITO−TiO₂ bilayer” refers to the combination of two layers, namely, a layer of nanoporous ITO and a layer of mesoporous TiO₂. Repetitive deposition of ITO−TiO₂ bilayers upon a glass plate, wherein each bilayer contains a layer of nanoporous ITO and a layer of mesoporous TiO₂ (“ITO−TiO₂ bilayer”), results in a multi-layered DSSC structure that contains multiple layers of TiO₂, with each TiO₂ layer active for electron transport and available for supporting light-absorbing dye molecules. In one embodiment, a multi-layered DSSC anode structure contains multiple ITO−TiO₂ bilayers and contains an overall TiO₂ layer thickness greater than 20 μm. Increasing the number of ITO−TiO₂ bilayers in a multi-layered DSSC structure increases the short circuit current. For example, a DSSC structure including two ITO−TiO₂ bilayers resulted in an approximate two-fold increase in short circuit current and an approximate 10% variation of open circuit voltage when compared to a DSSC anode structure including a single ITO−TiO₂ bilayer.

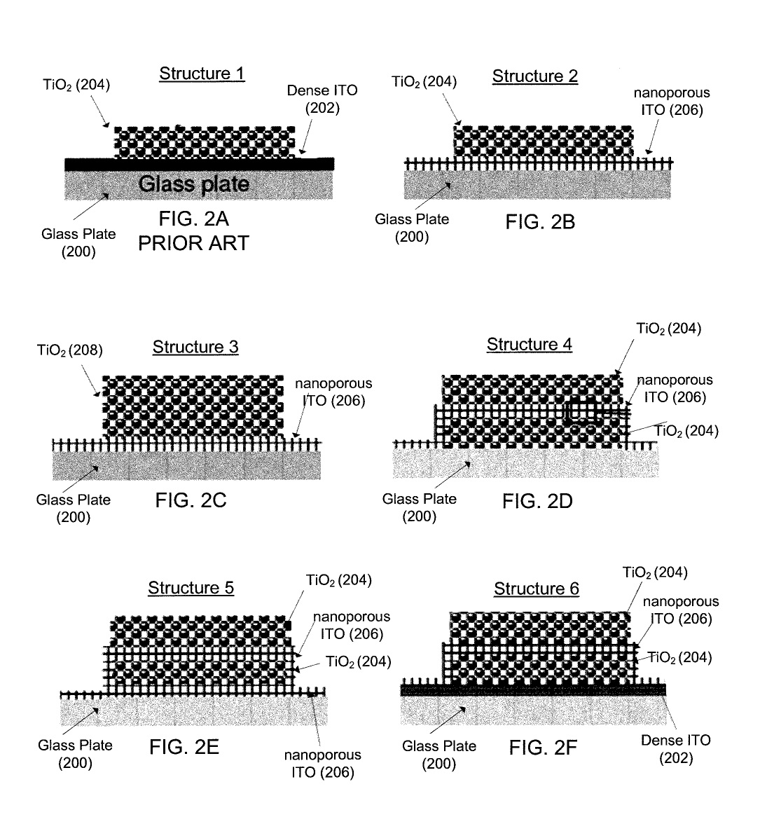

FIGS. 2A-2F show examples of improved multi-layered DSSC anode structures that were fabricated and evaluated. DSSC anode structures contain materials including glass, indium tin oxide (ITO) and titanium dioxide (TiO₂). The electron-collecting electrode is a dense ITO film and/or a nanoporous film made from ITO nanoparticles. Conventional DSSC anode Structure 1 of FIG. 2A displays consecutive layers including a glass plate 200, a dense ITO layer 202 and a TiO₂ layer 204. In one embodiment, improved multi-layered DSSC Structure 2 of FIG. 2B displays consecutive layers including a glass plate 200, a nanoporous ITO layer 206 which may be about 1 μm as an example, and a TiO₂ layer 204 which may be 10 μm thick in a particular embodiment. In one embodiment, improved multi-layered DSSC Structure 3 of FIG. 2C displays consecutive layers including a glass plate 200, a nanoporous ITO layer 206, and a TiO₂ layer 208, which may be about 20 μm thick in a particular embodiment. In one embodiment, improved multi-layered DSSC Structure 4 of FIG. 2D displays consecutive layers including a glass plate 200, a TiO₂ layer 204, a nanoporous ITO layer 206, and a TiO₂ layer 204. In one embodiment, improved multi-layered DSSC Structure 5 of FIG. 2E displays consecutive layers including a glass plate 200, a nanoporous ITO 206 layer, a TiO₂ layer 204, a nanoporous ITO layer 206, and a TiO₂ layer 204. In one embodiment, improved multi-layered DSSC Structure 6 of FIG. 2F displays consecutive layers including a glass plate 200, a dense ITO layer 202, a TiO₂ layer 204, a nanoporous ITO layer 206, and a TiO₂ layer 204.

In one embodiment, short-circuit current (I_{sc}) of a DSSC with a nanoporous ITO layer embedded between two mesoporous TiO₂ layers was 2.5-fold greater than a DSSC with a single ITO layer and a single TiO₂ layer. In another embodiment, circuit voltages (V_{oc}) of a DSSC with a nanoporous ITO layer embedded between two mesoporous TiO₂ layers was similar to a DSSC with a single ITO layer and a single TiO₂ layer.

Electron-hole recombination rates are higher in nanoporous ITO layer compared to dense ITO layers because of the higher surface area of the nanoporous ITO layer compared to the dense ITO layer. In one embodiment, the higher electron-hole recombination rate results in lower open circuit voltage of DSSCs with nanoporous ITO layers.

The following descriptions will show and describe, by way of examples, multi-layered DSSCs capable of solar-to-electrical energy conversion. The following examples describe preparation and characterization of ITO nanoparticles, ITO films, and DSSC anode structures. It is to be understood that these examples are provided by way of illustration and should not be unduly construed to limit the scope of what is disclosed herein.

### Example 1

### Preparation and Characterization of Indium Tin Oxide (ITO) Nanoparticles and ITO Films

This example teaches by way of illustration, not by limitation, preparation and characterization of ITO nanoparticles and ITO films. ITO nanoparticles were prepared by microwave-assisted synthesis, following the procedure described by Hammarberg et al., (E. Hammarberg, A. Prodi-Schwab and C. Feldmann, Thin Solid Films, 2008, 516, 7437-7442.) To prepare the ITO nanoparticles, 0.7 grams of InCl₃.4H₂O (99%) and 0.042 grams (5 mol % Sn⁴⁺, 95 mol % In³⁺)) or 0.084 grams (10 mol % Sn⁴⁺, 90 mol % In³⁺)) of SnCl₄.5H₂O (98%) were dissolved in 25 mL diethylene glycol (DEG) (99%). Another solution was prepared by dissolving 2.17 grams N(CH₃)₄OH.5H₂O (99%) and 1.4 ml deionized (DI) water in 25 mL diethylene glycol (DEG). All chemicals were from Sigma-Aldrich. These two solutions were placed into an oven at 353 K for 10 minutes and then quickly mixed at 353 K. A colorless solid immediately precipitated. The suspension was transferred to an autoclave, which was sealed and heated to 473 K and held at that temperature for 2 hours in a microwave oven (1000 W, 2.45 GHz) under vigorous stirring with a stir bar. The resulting ITO nanoparticles were collected by centrifugation and then washed by ethanol. After the centrifugation-washing process was repeated three times, the ITO nanoparticles were dried in a 333 K vacuum oven overnight.

A 5.5% ITO dispersion in diethylene glycol (DEG) was prepared by dispersing dry ITO nanoparticles in DEG and then sonicating for 2 hours. The resulting ITO dispersion in DEG was stable for more than 2 weeks. For ITO thin film preparation, the 5.5% ITO dispersion in DEG was spread on a glass plate and DEG was evaporated in a 353-K vacuum oven overnight. The ITO film was then placed into a 473-K oven for 2 hours and subsequently cooled to room temperature and rinsed in ethanol. This drying-rinsing process was repeated three times to remove residual DEG from the film. The thickness of the deposited ITO film was estimated from the mass of ITO deposited, the deposition area, and the estimated film porosity (33%). The ITO film thickness was also measured by a Dektak 6M surface profilometer with 12.5 μm diameter tip and a stylus force of 1 mg. The ITO film thickness was also measured by scanning electron microscopy (SEM). In one embodiment, the nanoporous ITO films are similar to those presented in FIG. 2B-2F.

ITO nanoparticles were characterized by Brunauer-Emmett-Teller (BET) surface area measurements using an Autosorb-1 system (Quantachrome Corporation). Nanoporous ITO thin films were characterized by field-emission scanning electron microscopy (FE-SEM), light transmittance measurements by Ultraviolet-visible spectroscopy (UV-VIS), and surface resistance measurements by a four-point probe. Prior to each adsorption measurement, the sample was outgassed in vacuum at 473 K for about 2 hours. Nitrogen adsorption isotherms were then measured at 77 K, and the BET method was used to calculate specific surface area. Light transmittance measurements were by UV-VIS (Agilent Technologies, G3172A).

Nanoparticle surface area, as measured by BET, for ITO nanoparticles including 5 mol % Sn⁺⁴ and 95 mol % In³⁺ was 38.9 m²/g. Nanoparticle surface area, as measured by BET, for ITO nanoparticles including 10 mol % Sn⁺⁴ and 90 mol % In³⁺ was 36.3 m²/g. These surface areas corresponded to average ITO nanoparticle sizes of 22 nm and 23 nm, respectively, assuming spherical, non-porous particles with a density of bulk In₂O₃.

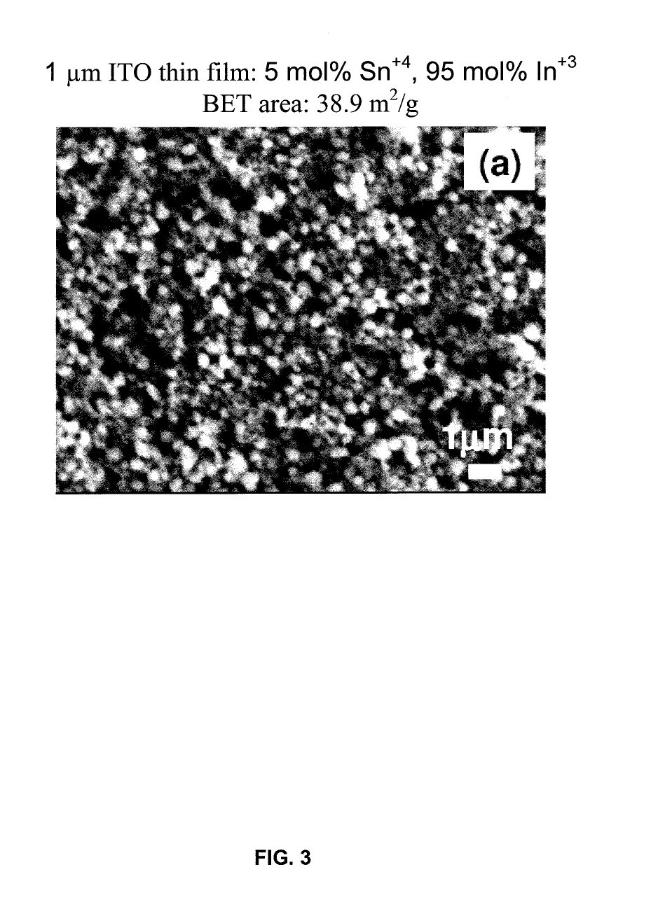

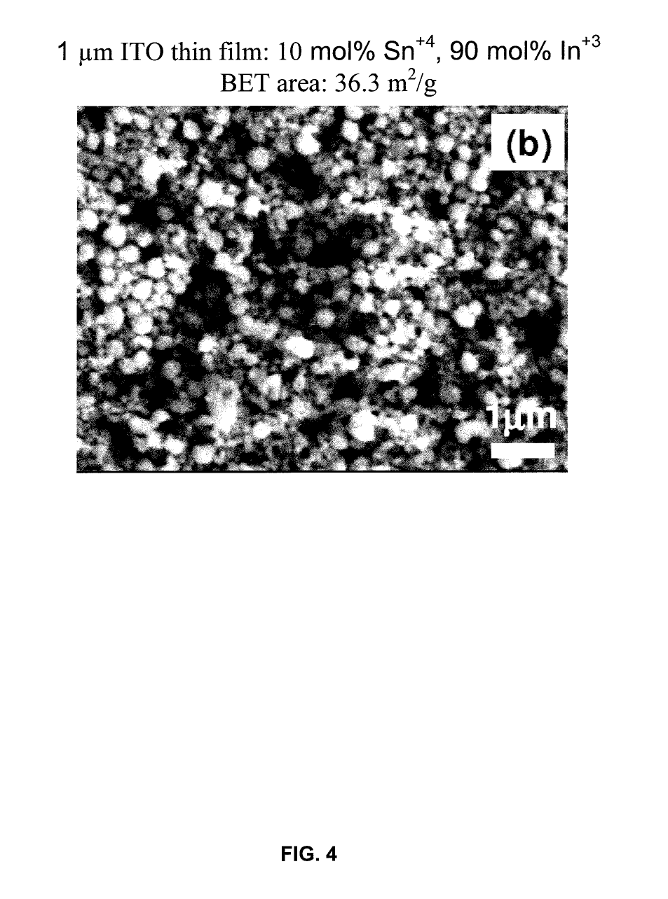

FIG. 3 shows a SEM image of a 1 μm thick ITO film including 5 mol % Sn⁺⁴ and 95% mol % In⁺³. FIG. 4 displays a SEM image of a 1 μm thick ITO film including 10 mol % Sn⁺⁴ and 90% mol % In⁺³. In one embodiment, the 1 μm thick nanoporous ITO films of FIGS. 2B-2F include either 5 mol % Sn⁺⁴ and 95% mol % In⁺³ or 10 mol % Sn⁺⁴ and 90% mol % In⁺³. The SEM images in FIG. 3 and FIG. 4 show a distribution of ITO nanoparticle sizes from 15 nm to 60 nm. Additionally, the SEM images in FIG. 3 and FIG. 4 display clusters of ITO nanoparticles with cavities between the ITO nanoparticle clusters. The nanoporous ITO films, as displayed in FIG. 3 and FIG. 4, were approximately 1 μm thick, as measured by a profilometer.

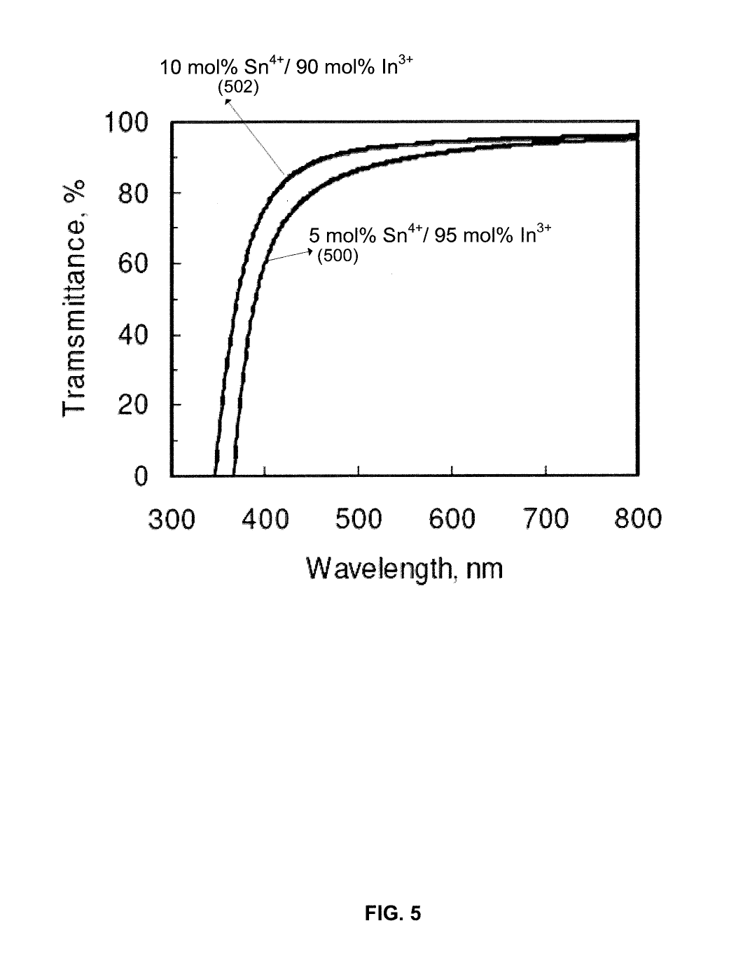

FIG. 5 shows UV-VIS transmission spectra of 1 μm thick ITO films, including either 5 mol % Sn⁺⁴ and 95% mol % In⁺³ (curve 500) or 10 mol % Sn⁺⁴ and 90% mol % In⁺³ (curve 502), after annealing at a temperature of 773 K in air for two hours. For wavelengths longer than 450 nm, the UV-VIS transmission spectra indicated good light transmittance at greater than 80% for ITO films including 5 mol % Sn⁺⁴ and 95% mol % In⁺³ and greater than 90% for ITO films including 10 mol % Sn⁺⁴ and 90% mol % In⁺³.

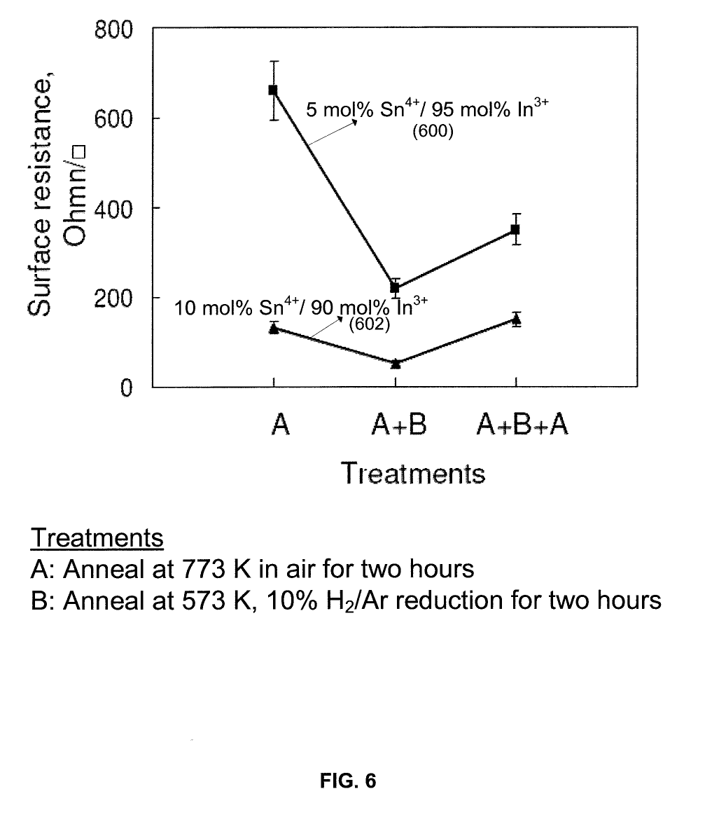

The surface resistance of ITO films (from FIG. 3 and FIG. 4) was measured by a four-point probe. Before annealing at elevated temperature, surface resistance of said ITO films were at least three orders of magnitude higher than that of the films annealed in air at a temperature of 773 K for 2 hours. Annealing increased contact between the particles. As displayed in FIG. 6, after annealing, an ITO film of 1 μm thickness including 5 mol % Sn⁴⁺ and 95 mol % In³⁺ (curve 600) had approximately five times higher surface resistance than an ITO film of 1 μm thickness including 10 mol % Sn⁴⁺ and 90 mol % In³⁺ (curve 602). When the ITO thin films were subsequently annealed in a reducing atmosphere (10% H₂/Ar), their surface resistance for both Tin (Sn) concentrations decreased approximately 60% (FIG. 6). Without being bound to any particular theory, it is hypothesized that hydrogen reduction recreated lattice defects, which increased free carrier concentration, and thus conductivity was higher. A second anneal in air restored the original surface resistance for the ITO film including 10 mol % Sn⁴⁺ and 90 mol % In³⁺. The surface resistance of the ITO film including 5 mol % Sn⁴⁺ and 95 mol % In³⁺ % Sn only increased to about 50% of its value after the first anneal. Oxygen refilled lattice defects, and reduced the number of free carriers, thus the conductivity decreased. For the 1 μm ITO films, the lowest specific resistivity obtained was 5.2×10⁻³ ohm·cm with an ITO film including 10 mol % Sn⁴⁺ and 90 mol % In³⁺ after H₂ reduction. This resistivity is an order of magnitude higher than that of dense ITO films (Sigma-Aldrich, 8-12 ohm/square and 120-160 nm thick) because of its high porosity.

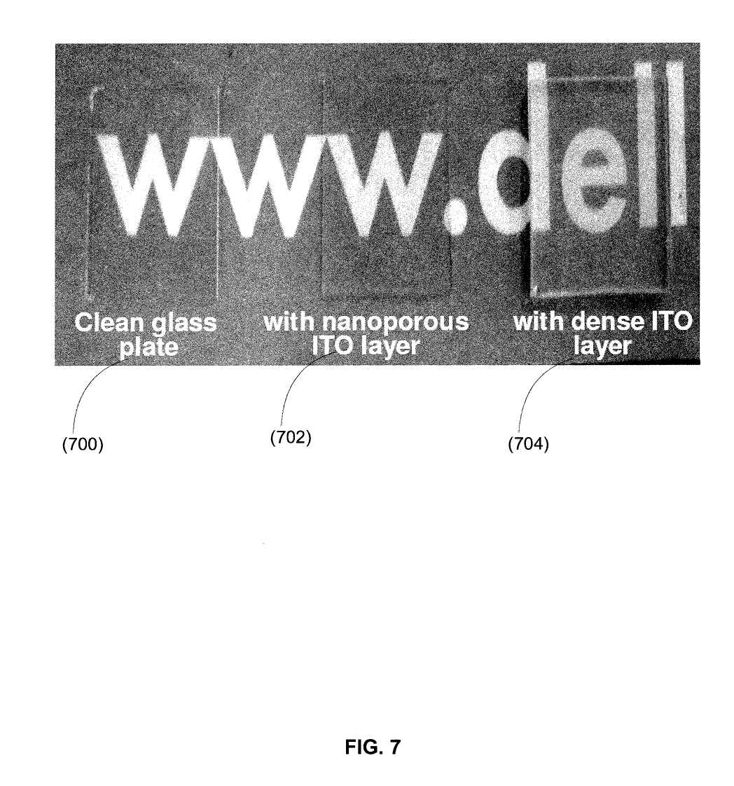

FIG. 7 shows the light transparency of a clean glass plate 700, a glass plate with a 1 μm thick nanoporous ITO layer with 10% Sn 702, and a glass plate with a dense ITO layer (120 nm-160 nm) 704. In particular, FIG. 7 shows that the glass plate 702 with a nanoporous ITO film with 10% Sn has the highest light transparency among the three glass plates 700, 702, and 704. Since the nanoporous ITO films including 10 mol % Sn⁴⁺ and 90 mol % In³⁺ had higher light transmittance and lower surface resistance compared to ITO films including 5 mol % Sn⁴⁺ and 95 mol % In³⁺, the nanoporous ITO films including 10 mol % Sn⁴⁺ and 90 mol % In³⁺ were used as the ITO layer(s) in DSSC structures 2-6.

### Example 2

### Preparation and Characterization of DSSC Anode Structures

This example illustrates the preparation and the characterization of exemplary DSSC anode structures. Mesoporous TiO₂ layer was prepared by a doctor-blade method using 25 weight (wt) % Degussa P25 TiO₂ dispersed in a 1:1 water/ethanol solution. The TiO₂ dispersion was prepared by hydrolyzing TiO₂ particles in DI water at 373 K for 60 minutes, adding ethanol to the resulting viscous gel, and then sonicating it for 2 hours to disperse the TiO₂. The TiO₂ thickness was measured by a Dektak 6M surface profilometer. The ITO oxide thin film was deposited on the TiO₂ layer as described in Example 1. Glass plates with a dense, 120-160 nm ITO layer that had a surface resistance of 8-12 ohm (Ω)/square were purchased from Sigma-Aldrich.

After the anode was sintered at a temperature of 773 K for 2 hours, it was cooled to a temperature of 373 K and soaked in 0.5 mM N719 dye (Everlight Chemical Industrial Corporation) in ethanol for 24 hours. The anode was then washed with ethanol and dried at a temperature of 333 K for at least 30 minutes. The anode was assembled with a platinized ITO counter electrode using a Surlyn 1702 polymer film. The electrolyte (0.8 M LiI, 0.04 M I₂, and 0.2 M 4-tert-butylpyridine in acetonitrile) was added between the two electrodes by capillary forces. The two electrodes were held together by hot melting the Surlyn seal at a temperature of 373 K under pressure. The active area of the DSSCs was approximately 0.25 cm².

Three DSSC cell samples were prepared for each improved, multi-layered DSSC structure presented in FIG. 2. The DSSC performance (i.e., photocurrent-voltage curve measurements) was evaluated for all DSSC samples. The variation between the measurements for three DSSC samples for each DSSC structure as presented in FIG. 2, was less than 10%. All measurements were based on the average performance of the three DSSC samples prepared for each DSSC structure that was presented in FIG. 2.

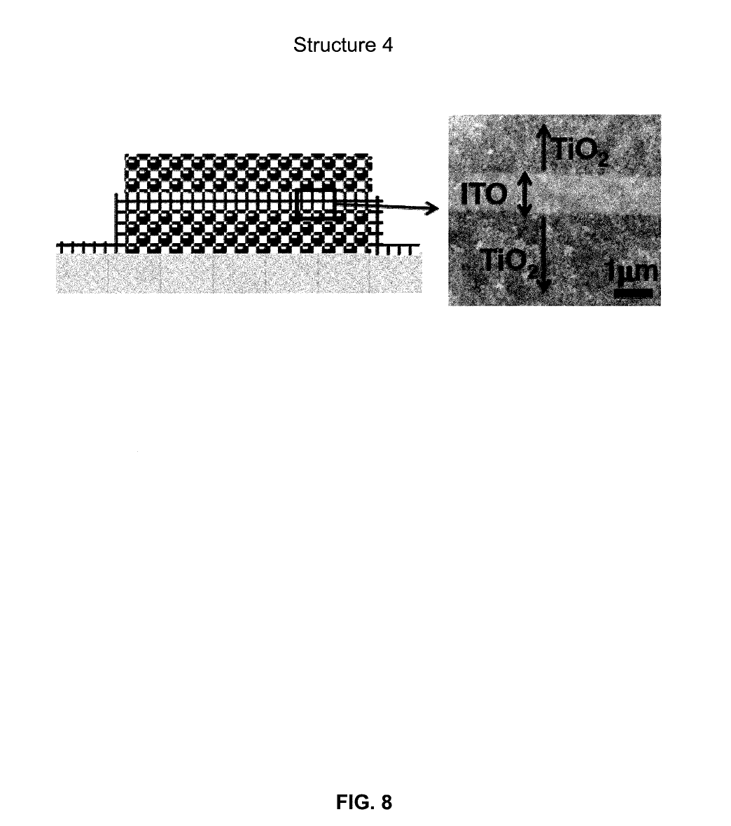

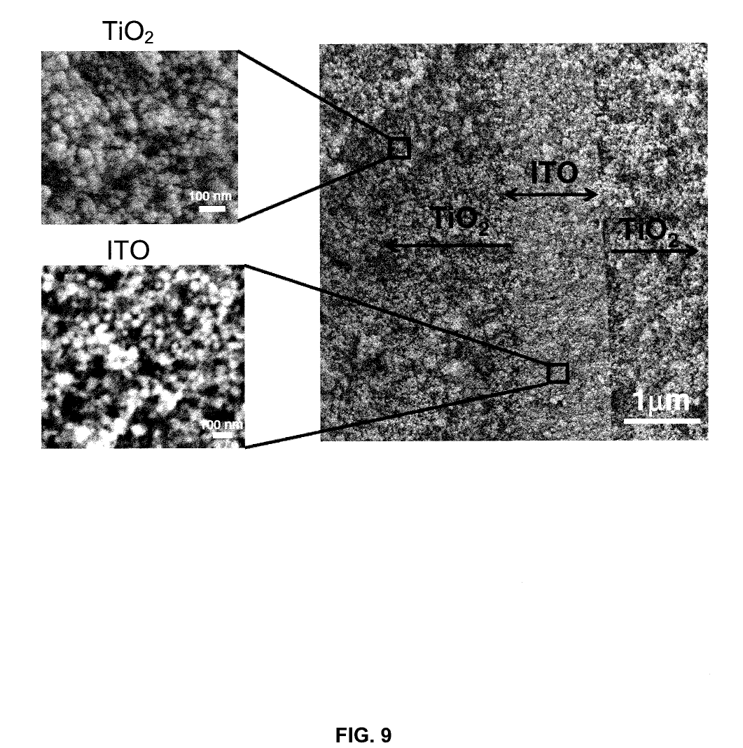

FIG. 8 shows that one exemplary deposition generated layered structure with a sharp interface between nanoporous ITO 206 and TiO₂ 204. The thickness measurements, in FIG. 3 and FIG. 4, are consistent with SEM cross-sectional characterization as shown in FIG. 8 for structure 4 of FIG. 2D. FIG. 9 displays detailed SEM images showing detailed layered of structure 4 of FIG. 2D.

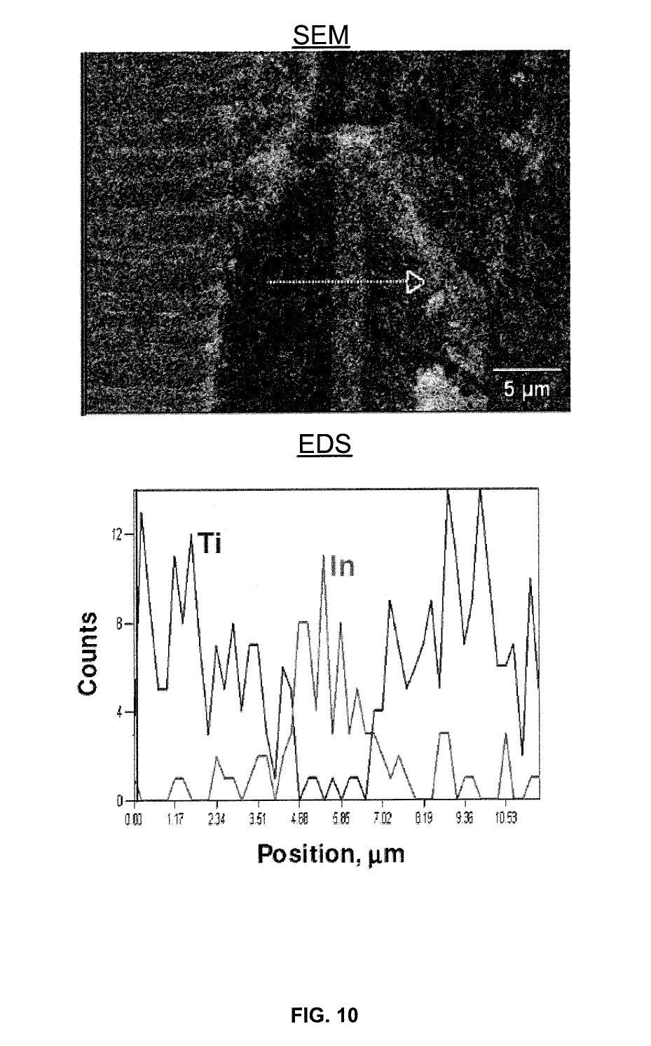

FIG. 10 shows characterization of multi-layered DSSC structure by SEM and energy-dispersive X-ray spectroscopy (EDS). The arrow presented on the SEM image indicates the direction and position of the line scan of EDS.

Photocurrent-voltage curves were measured using a 100-W metal halide lamp as the illumination source Infrared wavelengths were filtered out by a copper sulfate solution to minimize the temperature increase of the solar cell. The incident light intensity was adjusted to 50 mW/cm² (measured by a Daystar solar irradiance meter) by adjusting the distance between the light and the solar cell surface. Open circuit voltage decay was measured, after V_{oc} was stable under light, by shutting off the light and covering the solar cell with a metal plate.

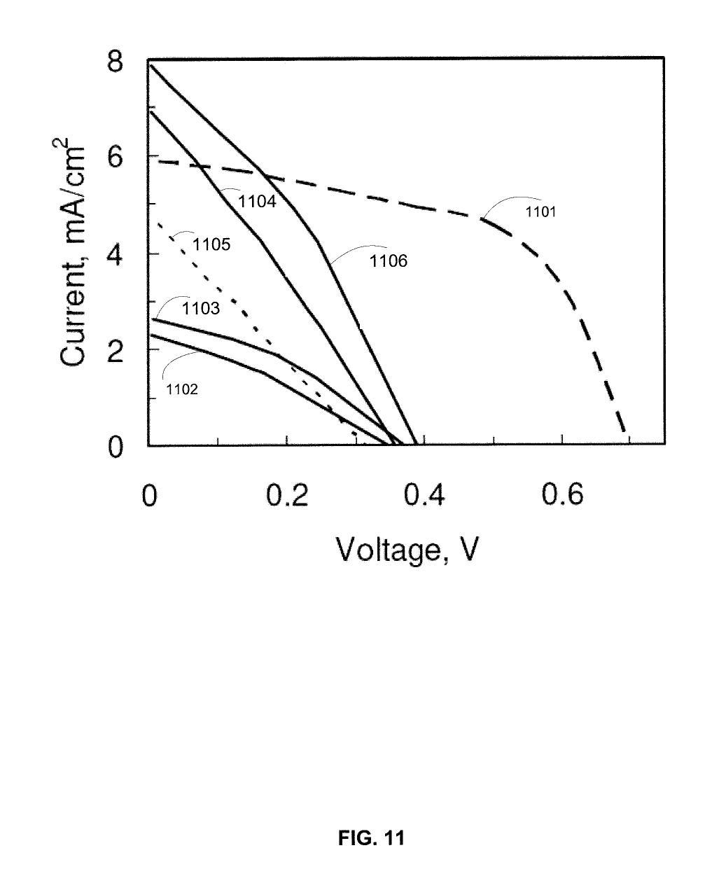

FIG. 11 shows photocurrent-voltage (I-V) curves, with input energy of 50 mW/cm², of various DSSC anode structures. FIG. 11 shows I-V curve 1101 for Structure 1 of FIG. 2A, I-V curve 1102 for Structure 2 of FIG. 2B, I-V curve 1103 for Structure 3 of FIG. 2C, I-V curve 1104 for Structure 4 of FIG. 2D, I-V curve 1105 for Structure 5 of FIG. 2E, and I-V curve 1106 for Structure 6 of FIG. 2F.

Structure 1, which is a conventional DSSC structure, includes a dense ITO layer that is used as the electron-collecting electrode. Structure 1 exhibited solar conversion efficiency of 4.5% and a fill factor of 0.55. The term “fill factor” refers to the ratio of (maximum output power)/(I_{sc}×V_{oc}), wherein I_{sc} is the short circuit current and V_{oc} is the open circuit voltage.

Structure 2 of FIG. 2B includes a nanoporous ITO layer. The open circuit voltage (V_{oc}) and the short circuit current (I_{sc}) of Structure 2 decreased to approximately 50% and 38%, respectively, of DSSC anode Structure 1. For Structure 2, the solar conversion efficiency was 0.5% and the fill factor was 0.31. The decreases of I_{sc} and V_{oc} for Structure 2 may be due to faster electron-hole recombination in the nanoporous ITO layer of Structure 2 because the nanoporous ITO layer of Structure 2 has a much higher surface area than the dense ITO layer of Structure 1.

FIG. 11 shows the I-V curves of DSSC anode Structures 2, 3, and 4, each of which has one nanoporous electron-collecting ITO layer. DSSC anode Structures 2, 3, and 4 used one nanoporous ITO layer as the electron-collecting electrode to enable comparison of the effects of the anode structure on solar conversion efficiency. Most photo-generated electrons are expected to be collected by the nanoporous ITO layer 206 in Structure 2, which has a 10 μm thick TiO₂ layer, as measured by a profilometer.

When the TiO₂ layer thickness was doubled to 20 μm in DSSC Structure 3, the short circuit current (I_{sc}) only increased 18%, and the open circuit voltage (V_{oc}) increased 6%; presumably the majority of the additional electrons generated were lost to electron-hole recombination. In contrast, placing a nanoporous ITO layer between two 10 μm TiO₂ layers, as in DSSC anode structure 4, increased I_{sc} by a factor of 2.5 over that obtained for a single 20 μm TiO₂ layer, as in DSSC anode structure 3. The V_{oc} was similar between structure 3 and structure 4. This observation indicates that there are still great possibilities to further increase the solar conversion efficiency of multi-layered DSSCs, if electrons, generated from TiO₂ layers thicker than 10 μm, are efficiently collected.

The electron-hole recombination rate in the nanoporous ITO layer 206 of structure 4 is expected to be higher than structure 2 and structure 3 because the electron density in the ITO layer of structure 4 is higher (i.e., more electrons are collected because of more TiO₂ surface area). However, the local I₃⁻ concentration is likely lower because the larger total thickness of TiO₂ layer(s) results in more recombination. This would decrease the percentage of the electrons that recombine with holes in the nanoporous ITO layer. In addition, the charge recombination in structure 4 may be limited by the ITO surface area. In other words, the recombination rate is unlikely linear to electron concentration because electrons need access to the surface to recombine. Thus, the electron recombination rate in structure 4 may not increase significantly compared to that in structure 2. Given all the above consideration, lower local I₃⁻ concentration and insignificant increase in the recombination rate in the nanoporous ITO layer, I_{sc} in structure 4 could more than double that of structure 2, as observed experimentally (see FIG. 11).

Structures 3, 4 and 5 have a total TiO₂ thickness of approximately 20 μm which exceeds the electron diffusion distance (10-15 μm) in mesoporous TiO₂. Structure 5, however, contains two nanoporous ITO layers instead of one nanoporous ITO layer of structure 4, and shows 30% and 10% lower I_{sc} and V_{oc} than structure 4. The bottom nanoporous ITO layer 206 in structure 5 introduces more electron-hole recombination centers. The bottom nanoporous ITO layer 206 is not necessary for electron collection because the middle nanoporous ITO layer 206 can collect most of photo-generated electrons from both TiO₂ layers, as shown for structure 4. Structure 5 had approximately 45% higher I_{sc} than structure 3, although V_{oc} of structure 5 is about 10% lower than structure 3. This large increase in I_{sc} is due to more efficient electron collection. The faster electron-hole recombination rate of structure 5, which is due to the bottom nanoporous ITO layer 206, lowers V_{oc}.

Structure 6, in which a dense ITO layer 202 replaced the bottom nanoporous ITO layer 206 of Structure 5. The resulting I_{sc} and V_{oc} increased 70% and 25%, respectively for structure 6 as compared to structure 5, as shown in FIG. 11. The I_{sc} of structure 6 is approximately 33% higher than that of the conventional DSSC with a dense ITO layer structure 1, but V_{oc} is about 45% lower due to electron-hole recombination in the middle nanoporous ITO layer. The solar conversion efficiency of structure 6 is 2.1%.

### Example 3

### Preparation and Characterization of DSSC Structures for Increased Open-Circuit Voltage

This example illustrates the preparation and the characterization of a DSSC with reduced electron hole recombination rates, improved solar-to electrical energy conversion efficiencies and increased open-circuit voltages. Passivation of the surface of ITO nanoparticles, in the ITO layer, is achieved by depositing a thin TiO₂ coating (e.g., 2-5 nm thick), which reduces the electron hole recombination rate and increases the open-circuit voltage. The passivated TiO₂-coated nanoporous ITO layer serves as a semiconducting support for light-absorbing dye molecules. For example, a TiO₂-coated nanoporous ITO layer provides similar surface area for supporting light-absorbing dye molecules as compared to a TiO₂ layer of similar thickness. Charge recombination in nanoporous ITO layers decreases the I_{sc} and V_{oc}.

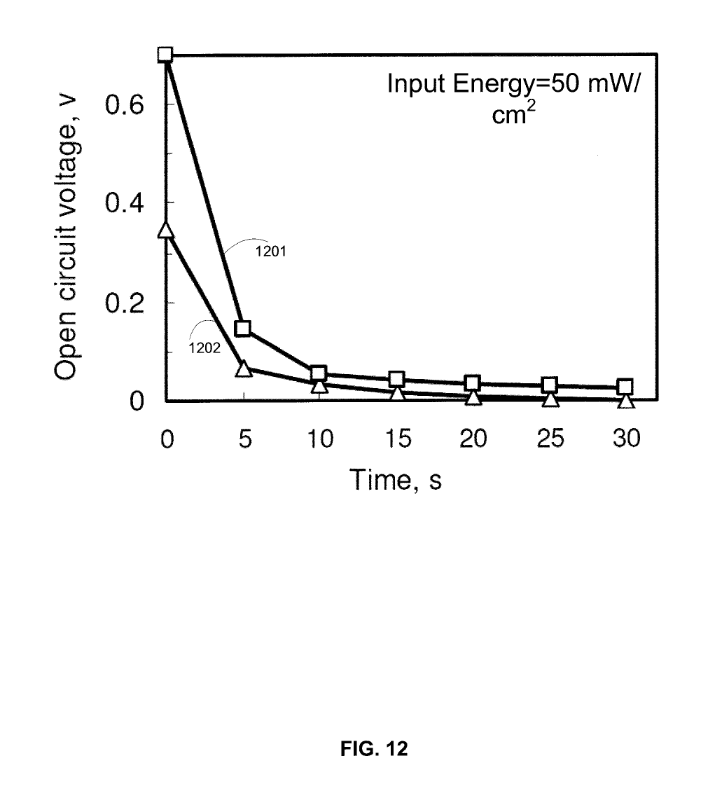

The dense ITO layer 202 has a much lower electron-hole recombination rate, as shown in FIG. 12 below. Passivating the nanoporous ITO layer 206 in structure 6, while allowing the redox pair to transport through it (i.e., keeping the ITO layer porous), further increases both I_{sc} and V_{oc}, and enhances the solar conversion efficiency. The nanoporous ITO layer, after passivation, has a similar electron-hole recombination rate as a dense ITO layer. Therefore, V_{oc} increases to ˜0.7 V and the I_{sc} significantly increases over that of structure 1. Passivating the nanoporous ITO layer 206 greatly enhances solar conversion efficiency compared to DSSCs with conventional single-layer TiO₂ structure.

FIG. 12 shows the V_{oc} decay for DSSC anode structures 1 and 2 after shutting off the light. This figure indicates that the charge recombination rate was faster for DSSC anode structure 2. In FIG. 12, curve 1201 is for Structure 1 of FIG. 2A and curved 1202 is for Structure 2 of FIG. 2B. The faster charge recombination rate likely results because structure 2 has about 200-times greater ITO surface area in contact with the I⁻/I₃⁻ redox pair in the electrolyte solution than structure 1. The surface area was estimated from the mass of ITO nanoparticles and their BET surface area. The open circuit voltage of structure 2 was approximately half that of structure 1 and the open circuit voltage of structure 2 decreased almost to zero in 30 seconds. The V_{oc} of structure 1 decreased to 0.04 V after 15 seconds and stayed almost constant until 30 seconds.

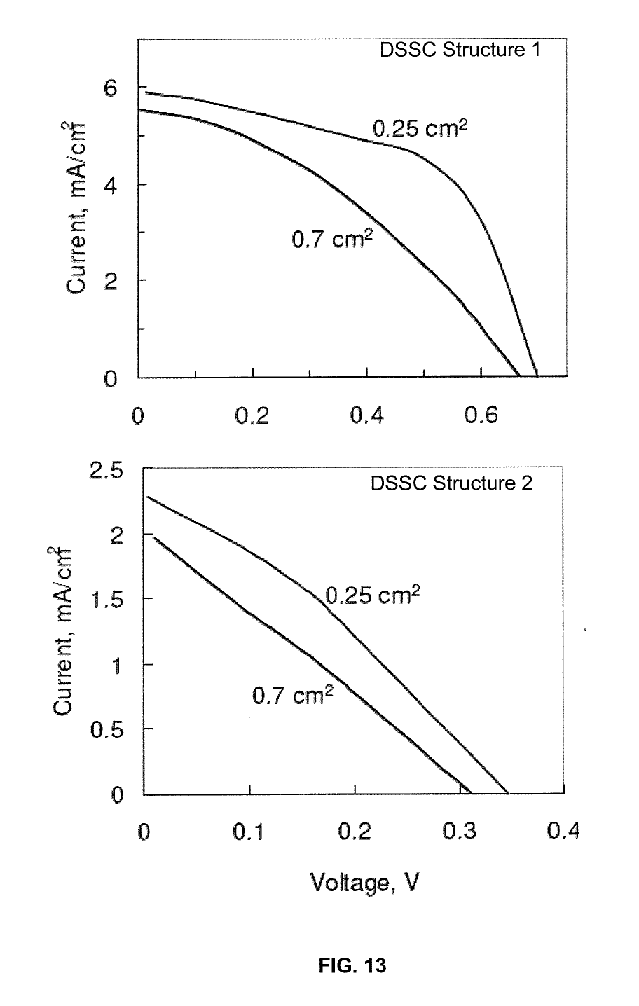

FIG. 13 shows I-V curves, with input energy of 50 mW/cm², of DSSCs structures 1 and 2 with different cells sizes, namely 0.25 cm² and 0.7 cm². Note that DSSC cell sizes influence the DSSC cell performance.

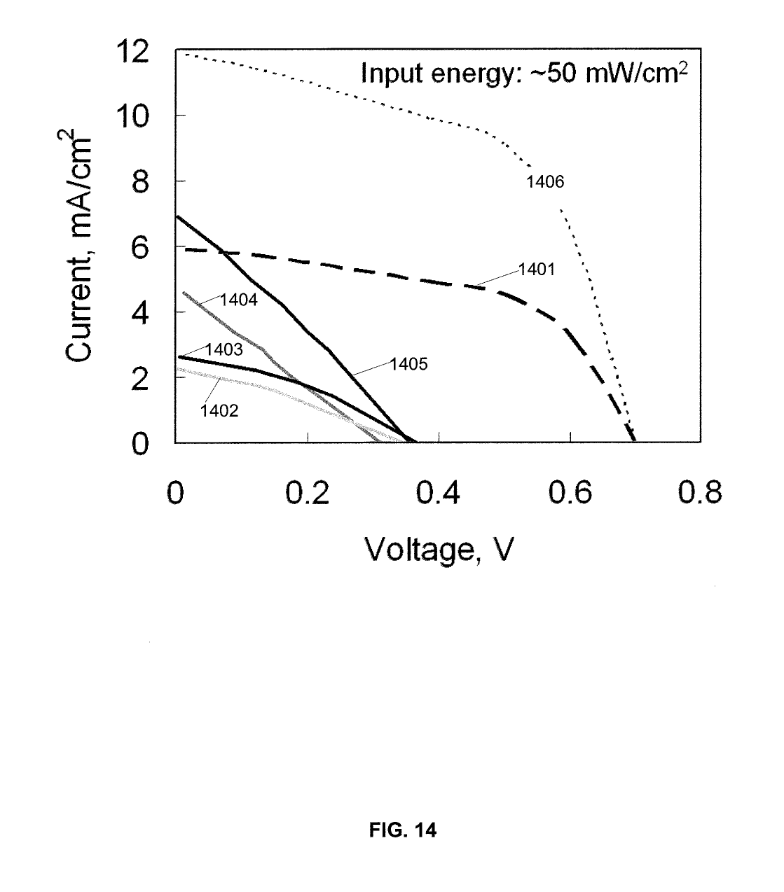

FIG. 14 demonstrates that multi-layered DSSC show up to three-fold increase in the short-circuit current as compared with DSSC structures without a multi-layered structure. FIG. 14 shows curve 1401 for Structure 1 of FIG. 2A, curve 1402 for Structure 2 of FIG. 2B, curve 1403 for Structure 3 of FIG. 2C, curve 1404 for Structure 5 of FIG. 2E, and curve 1405 for Structure 4 of FIG. 2D. FIG. 14 also demonstrates the results, curve 1406, for a DSSC Structure that contains ITO nanoparticles passivated with TiO₂.

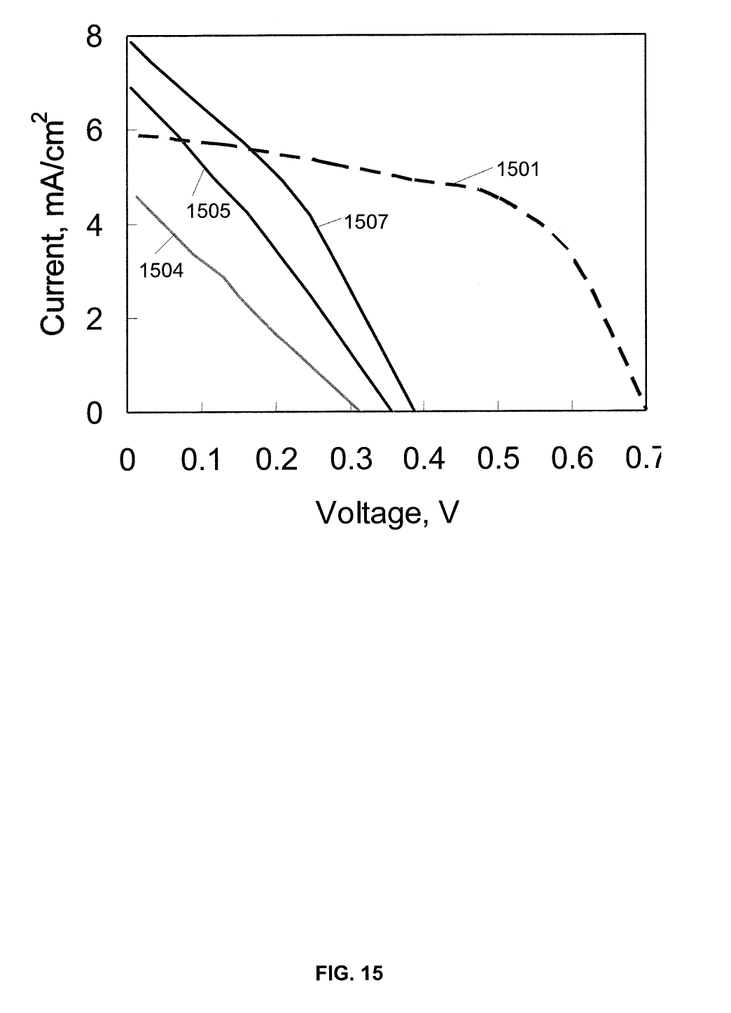

FIG. 15 displays I-V curves 1501, 1504, 1505, 1507 for various DSSC structures including Structure 6 of FIG. 2F. For example, FIG. 15 shows curve 1501 for Structure 1 of FIG. 2A, curve 1504 for Structure 5 of FIG. 2E, curve 1505 for Structure 4 of FIG. 2D, and curve 1507 for Structure 6 of FIG. 2F.

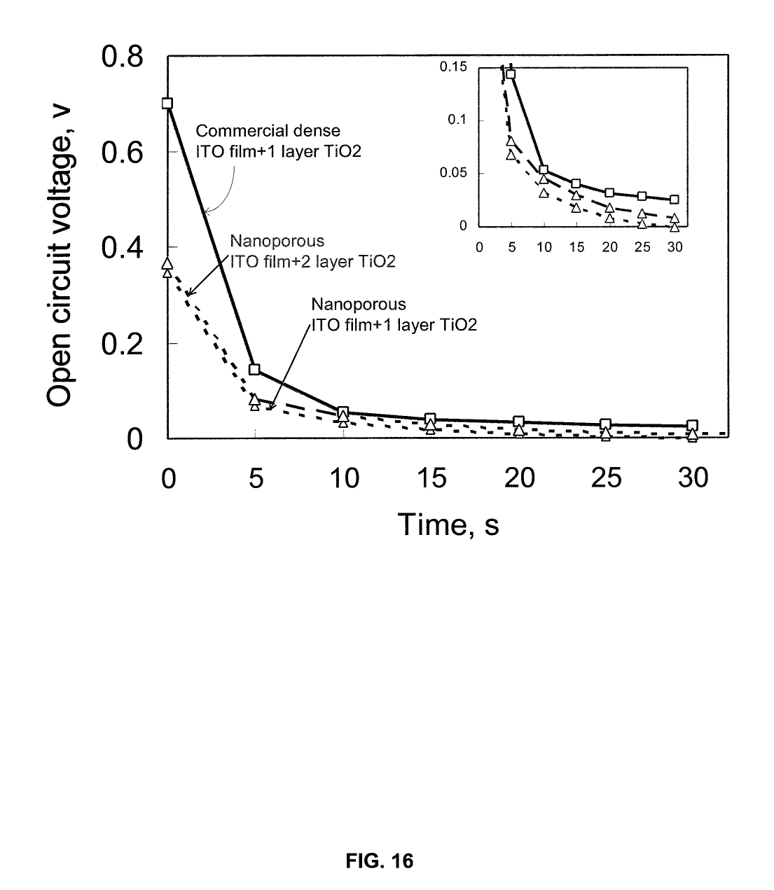

FIG. 16 displays the open circuit potential decay for a DSSC including a commercial dense ITO film and one layer of TiO₂, a DSSC including a nanoporous ITO film and two layers of TiO₂, and a DSSC including a nanoporous ITO film and one layer of TiO₂. As shown in FIG. 16, the open circuit potential decay indicates a faster recombination rate in nanoporous ITO layer, as compared to the commercial dense ITO layer.

The TiO₂-coated nanoporous ITO layer increases the total current owing to the short electron transporting distance, of approximately 2-5 nm, before reaching the electron-collecting material (i.e., interconnected network of ITO nanoparticles) which significantly suppresses the recombination rate in TiO₂.

### Example 4

### Preparation and Characterization of DSSC Structures for Efficient Solar Conversion Energy without Requirement for Sequential Layer Deposition

This example illustrates the preparation and the characterization of DSSCs with increased solar conversion efficiency and without a requirement for sequential layer deposition. An advanced multi-layered DSSC structure is prepared that that does not require sequential layer deposition. A nanoporous ITO layer more than 20 μm thick is deposited on dense ITO film and then coated with a 2-5 nm thick TiO₂ layer using ALD. The TiO₂ layer is deposited by exposing the nanoporous ITO layer to TiCl₄ to react with surface hydroxyl groups, and then exposing the resulting surface to H₂O to remove chlorine atoms and create fresh hydroxyls for a repeat sequence. Repeating these two reactions deposits a TiO₂ film.

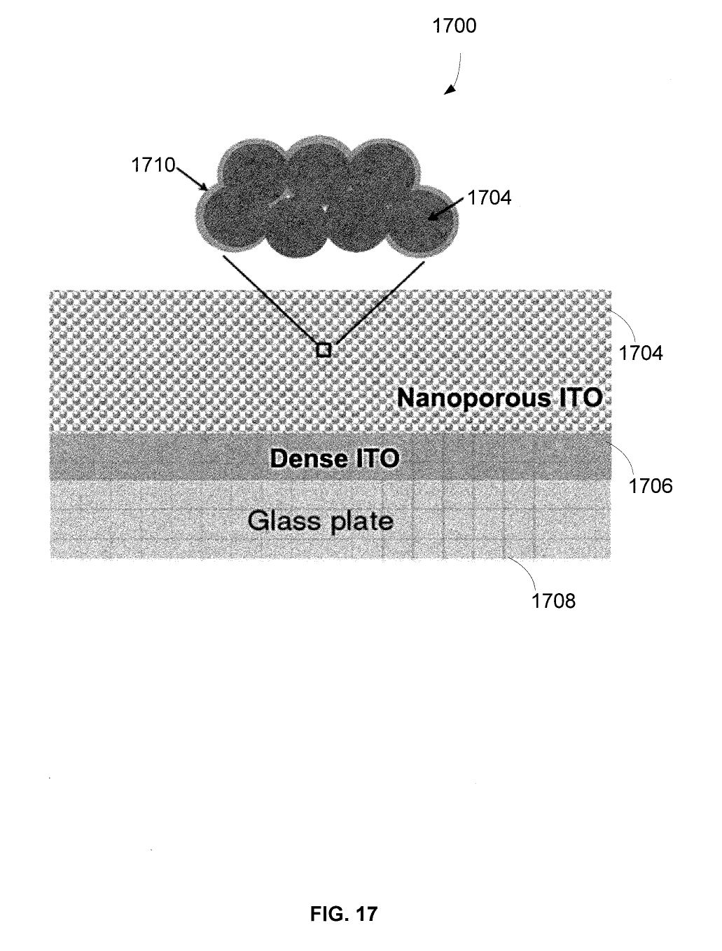

FIG. 17 shows the resulting DSSC anode structure 1700 that includes TiO₂ 1710 with thickness of about 2-5 nm, nanoporous ITO layer 1704, dense ITO layer 1706, and glass plate 1708. The electron transport distance of the DSSC anode structure 1700 would only be 2-5 nm. The resulting TiO₂ of DSSC anode structure 1700 has sufficient surface area to adsorb dye so that most of the light is absorbed. This structure only requires two preparation steps, but includes many thin TiO₂ layers in series, each of which would collect light and convert it to electrons. This cell has much higher efficiency because of the short electron transport distance and the larger amount of dye that could absorb light.

One of the advantages of the multi-layered DSSC structure is that the electron-transporting layers of the DSSC structure may have a total thickness equal or greater than the electron diffusion distance limitation. Additional advantage of the DSSC structure is that the porous ITO layer has negligible effects on light transparency. In contrast, in a tandem cell, scattering by platinum (Pt) nanoparticles on cathode and absorption by electrolyte solution can significantly reduce its efficiency.

Changes may be made in the above methods and systems without departing from the scope the instant disclosure. For example, the number of layers may be varied, or the composition, porosity and thicknesses of materials used in particular DSSCs may be varied. It should be noted that the matter contained in the above description or shown in the accompanying drawings should be interpreted as illustrative and not in a limiting sense. The following claims are intended to cover all generic and specific features described herein, as well as all statements of the scope of the present method and system and reasonable variations thereof, which, as a matter of language, might be said to fall therebetween.

What is claimed is:

1. A dye-sensitized solar cell (DSSC) anode, the DSSC anode comprising:
a first electron-collecting layer deposited on a substrate;
a first electron-transporting layer deposited on the first electron-collecting layer, the first electron-transporting layer containing light-absorbing dye;
a second nanoporous electron-collecting layer deposited on the first electron-transporting layer; and
a second electron-transporting layer deposited on the second porous electron-collecting layer, the second electron-transporting layer containing light-absorbing dye.

2. The DSSC anode of claim 1, wherein each of the first and second electron-transporting layers comprises a material selected from the group consisting of titanium dioxide (TiO₂), niobium pentoxide (Nb₂O₅), and zinc oxide (ZnO).

3. The DSSC anode of claim 1, wherein the first electron-collecting layer comprises at least one of indium tin oxide (ITO) nanoparticles and fluorinated tin oxide (FTO).

4. The DSSC anode of claim 1, wherein the substrate comprises a glass.

5. The DSSC anode of claim 1 wherein the second nanoporous electron-collecting layers comprises indium tin oxide (ITO) nanoparticles.

6. The DSSC anode of claim 5, wherein the ITO particles are passivated with a layer of TiO₂.

7. The DSSC anode of claim 1, wherein a total thickness of the first and second electron-transporting layers is greater than or equal to the electron diffusion limit of the electron-transporting layer material.

8. The DSSC anode of claim 1, wherein the first electron-collecting layer is a nanoporous or a dense layer.

9. The DSSC anode of claim 1, wherein the first and second electron-transporting layers each has a thickness of about 0.2-5 μm.

10. The DSSC anode of claim 1, wherein the ITO comprises 10 mol % Sn⁴⁺ and 90 mol % In³⁺.

11. A method for fabricating a DSSC anode, the method comprising:
depositing a first electron-collecting layer over a substrate;
forming a first electron-transporting layer over the first electron-collecting layer;
depositing a second nanoporous electron-collecting layer over the first electron-transporting layer; and
forming a second electron-transporting layer over the second nanoporous electron-collecting layer.

12. The method of claim 11, wherein each of the first and second electron-transporting layers comprises a material selected from the group consisting of titanium dioxide (TiO₂), niobium pentoxide (Nb₂O₅), and zinc oxide (ZnO).

13. The method of claim 11, wherein the second nanoporous electron-collecting layers comprises indium tin oxide (ITO) nanoparticles.

14. The method of claim 13 further comprising passivating a TiO₂ layer over the second nanoporous electron-collecting layer by atomic layer deposition

15. The method of claim 11, wherein the first electron-collecting layer comprises at least one of indium tin oxide (ITO) nanoparticles and fluorinated tin oxide (FTO).

16. The method of claim 11, wherein the total thickness of the first and second electron-transporting layer is equal to or greater than greater than or equal to the electron diffusion limit of the electron-transporting layer material.

17. The method of claim 11, wherein the first and second electron-transporting layers are mesoporous layers with pore diameters ranging from approximately 10 nm.

18. The method of claim 11, wherein each of the first and second electron-collecting layer is approximately 0.2-5 μm thick, and has pore diameters ranging from 10 nm to 30 nm.

19. A method for fabricating a DSSC anode, the method comprising:
depositing a dense indium tin oxide (ITO) layer over a substrate;
forming a nanoporous ITO layer comprising ITO nanoparticles over the dense ITO layer, wherein the nanoporous ITO layer has an order of magnitude higher resistivity than the dense ITO layer; and
passivating a titanium dioxide (TiO₂) layer over the nanoporous ITO layer.

20. The method of claim 19, wherein the nanoporous ITO layer has a thickness greater than 20 μm.

21. A dye-sensitized solar cell (DSSC), the DSSC comprising:
an anode comprising:
a first electron-collecting layer deposited on a substrate;
a first electron-transporting layer deposited on the first electron-collecting layer, the first electron-transporting layer containing light-absorbing dye;
a second nanoporous electron-collecting layer deposited on the first electron-transporting layer; and
a second electron-transporting layer deposited on the second porous electron-collecting layer, the second electron-transporting layer containing light-absorbing dye; and
a cathode in electrical connection with the anode.
